(19) United States
(12) Patent Application Publication
(10) Pub. No.: US 2026/0011578 A1
(43) Pub. Date: Jan. 8, 2026

(54) SUBSTRATE CLEANING APPARATUS AND CLEANING METHOD USING THE SAME

(71) Applicant: Samsung Electronics Co., Ltd., Suwon-si (KR)

(72) Inventors: Sangjine PARK, Suwon-si (KR); Ji Hwan PARK, Suwon-si (KR)

(21) Appl. No.: 19/007,183

(22) Filed: Dec. 31, 2024

(30) Foreign Application Priority Data
Jul. 8, 2024 (KR) 10-2024-0089728

(51) Int. Cl. H01L 21/67; H01L 21/02

(52) U.S. Cl. CPC H01L 21/67051; H01L 21/02057

(57) ABSTRACT

Provided is a substrate cleaning apparatus including a first support unit having a first support surface extending to a first radius and configured to support a substrate at a first cleaning area of the substrate, the first support unit configured to rotate around a central axis, a second support unit having a second support surface extending from a second radius larger than the first radius to a third radius larger than the second radius and configured to support the substrate at a second cleaning area, and configured to rotate around the central axis, a first nozzle unit configured to spray cleaning fluid onto the first cleaning area of the substrate when the substrate is supported by the second support unit, and a second nozzle unit configured to spray the cleaning fluid onto the second cleaning area of the substrate when the substrate is supported by the first support unit.

### CROSS-REFERENCE TO RELATED APPLICATION(S)

This application claims the benefit of Korean Patent Application No. 10-2024-0089728, filed on Jul. 8, 2024, in the Korean Intellectual Property Office, the disclosure of which is incorporated herein by reference.

### BACKGROUND

### 1. Field of the Invention

Example embodiments relate to a substrate cleaning apparatus and a method of cleaning a substrate using the same.

### 2. Description of the Related Art

In a semiconductor manufacturing process, unnecessary material layers, foreign substances, or debris may be deposited or adhered to a substrate surface at an unintended location, such as the backside of the substrate, and thus the substrate is cleaned to remove the unnecessary material layers, foreign substances, or debris.

For cleaning substrate surfaces, a substrate cleaning apparatus of the existing technology cleans a substrate by flipping the substrate, rotating the substrate by rubbing a rotating pin against the bevel edge of the substrate, and spraying a cleaning solution on the upper surface (the backside) of the substrate.

With the substrate cleaning apparatus of the existing technology, there is a risk of substrate damage due to friction between the substrate and the rotating pin, and the cleaning solution sprayed on the upper surface of the substrate may spread to undesirable areas and damage the substrate surface.

### SUMMARY

An aspect of the inventive concept provides a substrate cleaning apparatus that effectively cleans a target surface of a substrate (e.g., the backside of the substrate), and a method of cleaning the substrate using the same.

Another aspect of the inventive concept provides a substrate cleaning apparatus that minimizes damage to a substrate during a cleaning process, and a method of cleaning the substrate using the same.

The technical benefits achieved by the present example embodiments are not limited to the technical benefits described above, and other technical benefits may be inferred from the following example embodiments by those skilled in the art.

According to an aspect, a substrate cleaning apparatus includes a first support unit having a first support surface extending to a first radius and configured to support a substrate at a first cleaning area of the substrate when the substrate is loaded in the substrate cleaning apparatus, the first support unit being configured to rotate around a central axis, a second support unit including an accommodation space accommodating the first support unit, the second support unit having a second support surface extending from a second radius larger than the first radius to a third radius larger than the second radius and configured to support the substrate at a second cleaning area when the substrate is loaded in the substrate cleaning apparatus, the second support unit being configured to rotate around the central axis, a first nozzle unit configured to spray a cleaning fluid upward at an area within the second radius onto the first cleaning area of the substrate when the substrate is supported by the second support unit, and a second nozzle unit configured to spray the cleaning fluid upward at an area external to the first radius onto the second cleaning area of the substrate when the substrate is supported by the first support unit.

According to another aspect, there is provided a method of cleaning a substrate, the method including rotating a first support unit around a central axis with the first support unit supporting a substrate at a first cleaning area of the substrate, wherein the first support unit has a recess accommodating a first nozzle unit, moving a second support unit in a direction parallel to the central axis to space the second support unit from the substrate, wherein the second support unit includes an accommodation space to accommodate the first support unit, and spraying cleaning fluid onto a second cleaning area of the substrate that is outside of the first cleaning area of the substrate with a second nozzle unit.

According to another aspect, there is provided a substrate cleaning apparatus including a first support unit having a first support surface configured to support a substrate rotate around a central axis, a second support unit having a second support surface configured to support the substrate at a location radially external to the first support surface and rotate around the central axis, and suitable to relatively move in a direction parallel to the central axis with respect to the first support unit, a first nozzle unit coupled to the first support unit and comprising a plurality of nozzle holes arranged along a direction intersecting the central axis, wherein the plurality of nozzle holes are configured to spray cleaning fluid at a location radially internal to the second support surface, and a second nozzle unit disposed to be spaced from the first support unit and the second support unit, the second nozzle unit being configured to spray the cleaning fluid onto the bottom of the substrate while moving in a direction perpendicular to the central axis.

Additional aspects of example embodiments will be set forth in part in the description which follows and, in part, will be apparent from the description, or may be learned by practice of the disclosure.

According to example embodiments, it is possible to provide a substrate cleaning apparatus and a method of cleaning a substrate using the same by which the surface to be cleaned is effectively cleaned while being stably supported to be cleaned.

According to example embodiments, it is possible to effectively clean a surface of a substrate without contact with any part of the substrate other than the surface to be cleaned.

According to example embodiments, it is possible to prevent a cleaning fluid sprayed onto a substrate from spreading to other parts other than the surface to be cleaned.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is an exemplary perspective view of a substrate cleaning apparatus according to an example embodiment;

FIG. 2 is an exemplary exploded perspective view of a substrate cleaning apparatus according to an example embodiment;

FIG. 3 is an exemplary plan view of a substrate cleaning apparatus according to an example embodiment;

FIG. 4 is an exemplary configuration diagram of a substrate cleaning apparatus according to an example embodiment;

FIG. 5 is a reference diagram for explaining an example of cleaning a portion of a substrate while a first support unit supports a substrate according to an example embodiment;

FIG. 6 is an exemplary cross-sectional view of a substrate cleaning apparatus in a state where a first support unit supports a substrate according to an example embodiment;

FIG. 7 is a reference diagram for explaining an example of cleaning a portion of a substrate while a second support unit supports the substrate according to an example embodiment;

FIG. 8 is an exemplary cross-sectional view of a substrate cleaning apparatus illustrating a state in which a second support unit supports a substrate according to an example embodiment;

FIG. 9 is an exemplary perspective view of a first support unit and a first nozzle unit of a substrate cleaning apparatus according to an example embodiment;

FIG. 10 is an exemplary side view that is viewed from the “A” direction of FIG. 9;

FIG. 11 is an exemplary top view of a first nozzle unit included in a substrate cleaning apparatus according to an example embodiment;

FIG. 12 is an exemplary front view of a first nozzle unit according to the example embodiment illustrated in FIG. 11;

FIG. 13 is an exemplary top view of a first nozzle unit included in a substrate cleaning apparatus according to an example embodiment; and

FIG. 14 is an exemplary front view of a first nozzle unit according to the example embodiment illustrated in FIG. 13.

### DETAILED DESCRIPTION

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

The example embodiments described in this specification and the configurations shown in the drawings are only examples of embodiments of the present disclosure, and do not represent all variations of the embodiments encompassed within the inventive concept disclosed in the present disclosure. Accordingly, at the time of filing the present disclosure, there may be various equivalents and modifications to the disclosed embodiments that are covered by the inventive concept. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

In the following description, singular expressions include plural expressions unless the context clearly dictates otherwise. For example, the description of a single element applies to multiple instances of the same elements. Additionally, the description of a single element does not preclude multiple instances of the element being present.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

It will be understood that, when an element (for example, a first element) is “(operatively or communicatively) coupled with/to” or “connected to” another element (for example, a second element), the element may be directly coupled with/to or connected to another element, in which case the elements contact one another, and/or the element may be indirectly coupled with/to or connected to, in which case there may be an intervening element (for example, a third element) between the element and another element, such that the elements contact the intervening element but do not contact one another.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed. The terms “have,” “may have,” “include,” and “may include” as used herein indicate the presence of corresponding features (for example, elements such as numerical values, functions, operations, or parts), and do not preclude the presence of additional features.

In the following description, expressions such as an upper side, top, a lower side, bottom, a side, front and a back side are used for ease of description and are expressed based on the direction shown in the drawing of the embodiment being described. If the orientation of the object in the drawing changes, the expressions may change in relation to the changed orientation. The shapes and sizes of elements in the drawings may be exaggerated for clearer explanation.

Hereinafter, a substrate cleaning apparatus and a method of cleaning a substrate using the substrate cleaning apparatus according to example embodiments will be described with reference to the attached drawings.

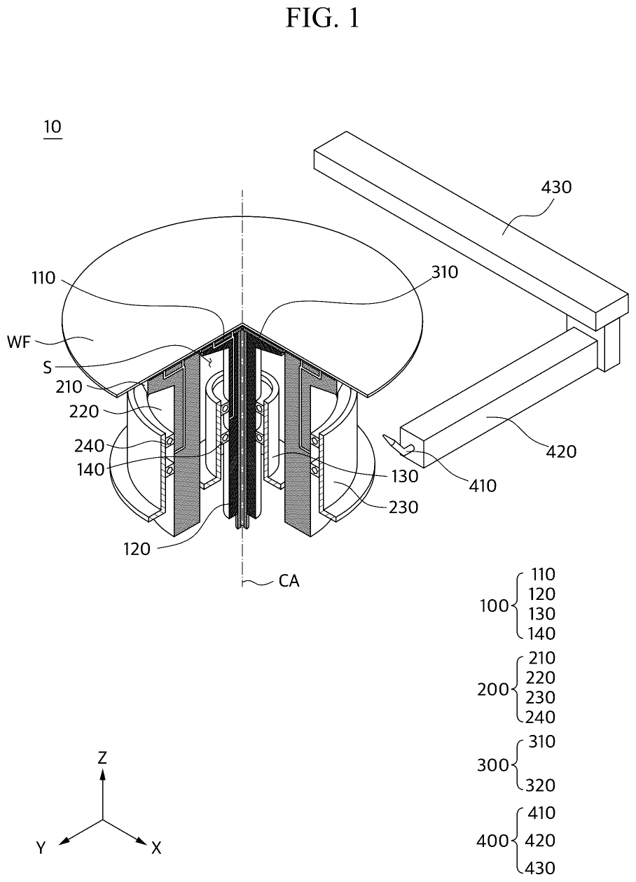

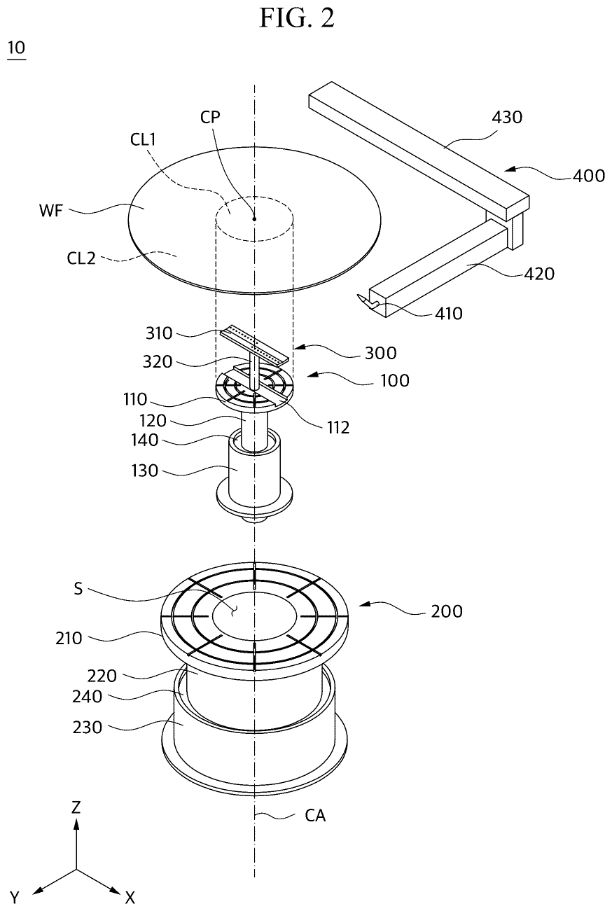

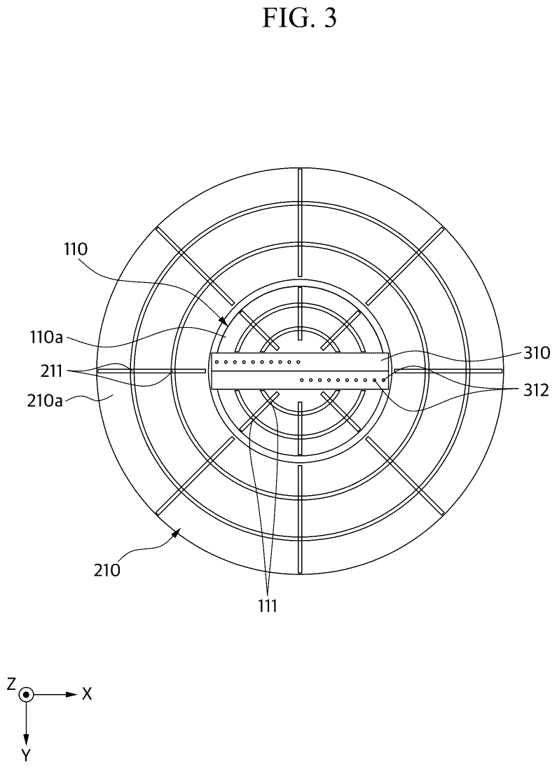

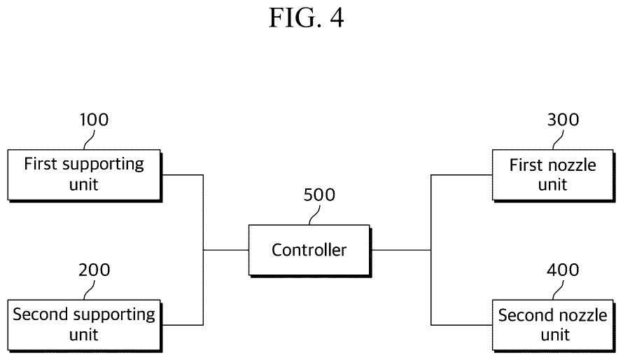

FIG. 1 is a perspective view of a substrate cleaning apparatus 10 according to an example embodiment. FIG. 2 is an exploded perspective view of the substrate cleaning apparatus 10 according to an example embodiment. FIG. 3 is a plan view of the substrate cleaning apparatus 10 according to an example embodiment. FIG. 4 is a configuration diagram of the substrate cleaning apparatus 10 according to an example embodiment.

According to some example embodiments, the substrate cleaning apparatus 10 may be a device for cleaning a substrate WF (e.g., a wafer) in a semiconductor manufacturing process. For example, the substrate cleaning apparatus 10 may perform a cleaning process in which a solution or gas is sprayed onto a surface of the substrate WF (e.g., a backside of the substrate) and contamination or foreign substances on the surface of the substrate WF are removed. The surface of the substrate WF may refer to the surface of a base substrate WF such as an initial semiconductor substrate forming the base of the wafer in the final wafer product, such as a bulk semiconductor substrate (e.g., formed of crystalline silicon), an silicon on insulator (SOI) substrate, etc., or may refer to a surface of a material layer formed on the base substrate WF.

In some example embodiments, the substrate cleaning apparatus 10 may remove an unnecessary material layer on the substrate WF through a wet or dry cleaning process. Specifically, in the semiconductor manufacturing process, an unnecessary material layer may be deposited on the bevel edge or the lower surface (the bottom) of the substrate WF, and according to some example embodiments, the substrate cleaning apparatus 10 may effectively clean the substrate WF to remove the unnecessary material layer on the bevel edge or the lower surface of the substrate WF.

In existing technology, in order to clean the bottom of the substrate, the substrate is placed upside down (e.g., inverted) so that the bottom of the substrate faces the upper side of a substrate cleaning apparatus, the substrate is fixed by bringing the bevel edge of the substrate into contact with rotating pins, and the substrate is rotated with the bottom of the substrate exposed to the upper side of the substrate cleaning apparatus. In the process of the existing technology, a process inefficiency occurs as a result of including an inversion process to invert the substrate, and the thin bevel edge of the substrate is susceptible to damage from repeated friction and contact with the rotating pins. Further, in the substrate inversion process, there is a possibility that the cleaning solution sprayed on the bottom of the substrate may flow down due to gravity to the upper surface of the substrate (which is temporarily facing downward) and damage the necessary material layer (hereinafter referred to as the “effective material layer”) of the upper surface of the substrate.

According to some example embodiments, the substrate cleaning apparatus 10 may clean a surface (e.g., the bottom surface) of the substrate WF while supporting the substrate WF at the surface to be cleaned, without inversion of the substrate WF. According to the example embodiments, in the substrate cleaning apparatus 10, a surface to be cleaned of the substrate WF (e.g., the bottom surface), which may be referred to as a target surface, may be divided into a plurality of areas to be cleaned, and each of the areas may be cleaned sequentially. The areas may each be a circular area or an annular area. The bottom of the substrate WF may be divided into a plurality of areas to be cleaned including a first cleaning area CL1 and a second cleaning area CL2, and while one of the areas is supported on the support unit of the substrate cleaning apparatus 10, the substrate cleaning apparatus 10 may clean the remaining areas that are not supported on the support unit. Hereinafter, the configuration of the substrate cleaning apparatus 10 will be described in more detail with reference to FIGS. 1 to 4.

According to some example embodiments, the substrate cleaning apparatus 10 may include a first support unit 100 and a second support unit 200 that are each configured to support and rotate the target surface of the substrate WF, and a first nozzle unit 300 and a second nozzle unit 400 that are each configured to spray a cleaning fluid onto the target surface of the substrate WF while the substrate WF rotates.

According to some example embodiments, the first support unit 100 and the second support unit 200 of the substrate cleaning apparatus 10 may support the substrate WF at different areas of the substrate WF. For example, referring to FIG. 1 and FIG. 2, the substrate cleaning apparatus 10 may include a first support unit 100 configured to support the substrate WF at the first cleaning area CL1 of the substrate WF, and a second support unit 200 configured to support the substrate at the second cleaning area CL2 of the substrate WF. The first cleaning area CL1 may be a circular area having a radius less than the radius of the substrate WF and the second cleaning area CL2 may be an annular area external to the first cleaning area CL1 and may include the annular area between an inner radius equal to or greater than the radius of the circular area and an outer radius that is equal to or less than the radius of the substrate WF.

In some example embodiments, the first support unit 100 of the substrate cleaning apparatus 10 may be configured to selectively support the substrate at the first cleaning area CL1 of the substrate WF. For example, referring to FIG. 1 and FIG. 2, the first support unit 100 may include a first supporting body 120 (e.g., a first support) extending along a central axis CA formed in the direction intersecting the bottom of the substrate WF, and a first substrate mount 110 for mounting the substrate WF is positioned at an end portion of the first supporting body 120. The first support mount 110 has a flange shape corresponding to the first cleaning area CL1 of the substrate WF when the substrate WF is mounted in the substrate cleaning apparatus 10. The substrate WF may be supported on the first support unit 100 with the substrate WF secured to the first substrate mount 110 (for example, a first surface 110a for substrate mounting of FIG. 3), which is the upper surface of the first substrate mount 110 of the first support unit 100.

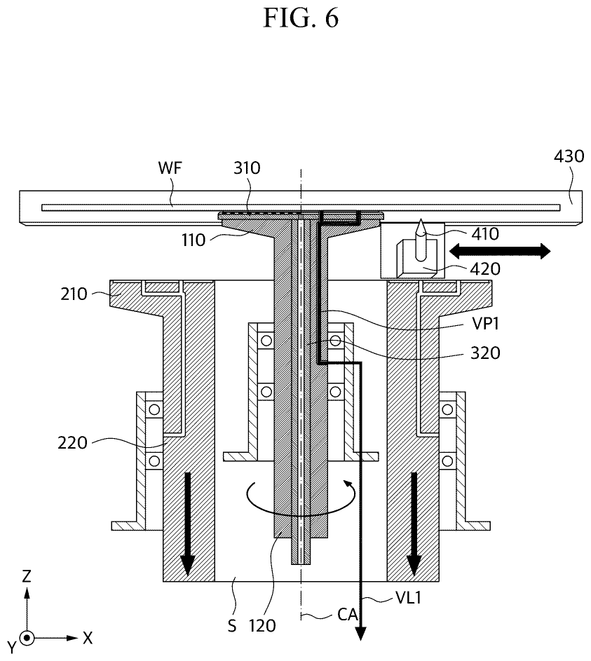

In some example embodiments, the first support unit 100 may rotate the substrate WF by rotating around the central axis CA while supporting the substrate WF thereby causing the substrate WF to rotate. The substrate WF may be secured on the first substrate mount 110 by vacuum adsorption. For example, referring to FIG. 2 and FIG. 3 together, a plurality of vacuum holes 111 may be provided on the first surface 110a and the vacuum holes 111 may have a negative pressure or vacuum applied to vacuum-adsorb the substrate WF. The plurality of vacuum holes 111 may be connected to a first vacuum flow path (for example, a first vacuum flow path VP1 in FIG. 6) formed inside the first support unit 100. The first vacuum flow path VP1 may be connected to a vacuum pump outside the substrate cleaning apparatus 10. Accordingly, a vacuum line (for example, a vacuum line VL1 in FIG. 6) extending from the vacuum pump to the vacuum holes 111 may be provided to connect the vacuum pump to the substrate cleaning apparatus 10. As negative pressure is formed in the vacuum line VL1, the substrate WF is tightly fixed to the first substrate mount 110, and the substrate's WF position relative to the first support unit 100 may be fixed. In such a state, as the first support unit 100 rotates around the central axis CA, the substrate WF may rotate together with the first support unit 100.

In some example embodiments, the first support unit 100 of the substrate cleaning apparatus 10 may further include a first support frame 130 that supports the first supporting body 120 in a way that the first supporting body 120 may rotate. The first support frame 130 may be liftably connected to a work table or work surface (not illustrated) on which the substrate cleaning apparatus 10 is installed. A first friction reducing member 140 may be placed between the first support frame 130 and the first supporting body 120 to reduce rotational friction force. For example, the first friction reducing member 140 may be a bearing whose outer surface is connected to the first support frame 130 and whose inner surface is connected to the first supporting body 120.

In some example embodiments, the second support unit 200 of the substrate cleaning apparatus 10 may be configured to support the second cleaning area CL2 on one side of the substrate WF. For example, referring to FIG. 1 and FIG. 2, the second support unit 200 may include a second supporting body 220 (e.g., a second support) extending along the central axis CA, and a second substrate mount 210 for mounting the substrate, which is positioned at the end portion of the second supporting body 220. The second substrate mount has a flange shape corresponding to the second cleaning area CL2 of the substrate WF when the substrate is mounted in the substrate cleaning apparatus. The central axis CA of the second support unit 200 may be the same as the central axis CA of the first support unit 100 (e.g., they may be coaxial). The substrate WF may be supported by the second support unit 200 with the substrate WF secured to a surface of the second substrate mount 210 (for example, a second surface 210a for substrate mounting in FIG. 3) which is the upper surface of the second substrate mount 210 of the second support unit 200.

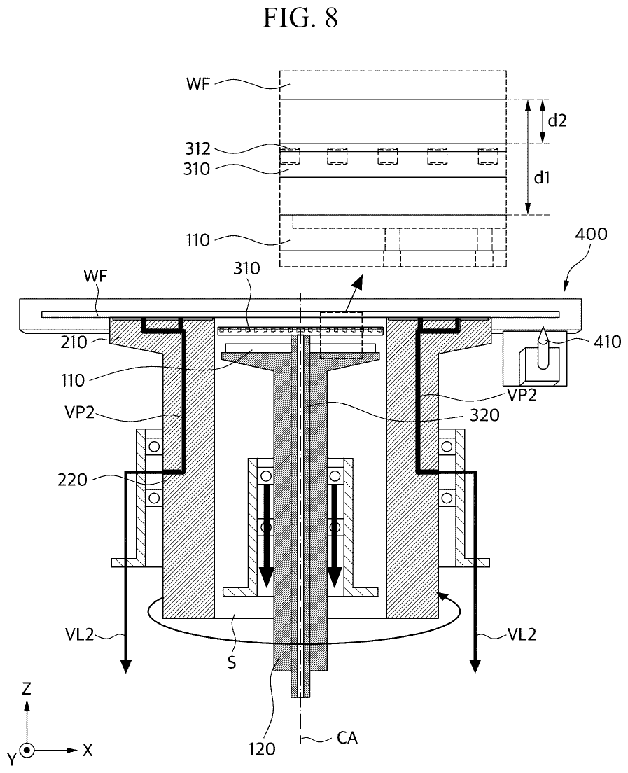

In some example embodiments, the second support unit 200 may rotate the substrate WF by rotating around the central axis CA while supporting the substrate WF thereby causing the substrate WF to rotate. The substrate WF may be secured to the second substrate mount 210 by vacuum adsorption on the second substrate mount 210. For example, referring to FIG. 2 and FIG. 3 together, a plurality of vacuum holes 211 for vacuum-adsorbing the substrate WF may be provided on the second surface 210a of the second substrate mount 210. The plurality of vacuum holes 211 may be connected to a second vacuum flow path (for example, a second vacuum flow path VP2 in FIG. 8) formed inside the second support unit 200. The second vacuum flow path VP2 may be connected to a vacuum pump outside the substrate cleaning apparatus 10. Accordingly, a vacuum line (for example, a vacuum line VL2 in FIG. 8) extending from the vacuum pump to the vacuum holes 211 may be provided. As negative pressure is formed in the vacuum line VL2, the substrate WF is tightly fixed to the second substrate mount 210, and the position of the substrate WF relative to the second support unit 200 may be fixed. In this state, as the second support unit 200 rotates around the central axis CA, the substrate WF may rotate together with the second support unit 200.

In some example embodiments, the second support unit 200 of the substrate cleaning apparatus 10 may further include a second support frame 230 that supports the second supporting body 220 in a way that the second supporting body 220 may rotate. The second support frame 230 may be liftably connected to a work table (not illustrated) on which the substrate cleaning apparatus 10 is installed. A second friction reducing member 240 may be placed between the second support frame 230 and the second supporting body 220 to reduce rotational friction force. For example, the second friction reducing member 240 may be a bearing whose outer surface is connected to the second support frame 230 and whose inner surface is connected to the second supporting body 220.

In some example embodiments, the first support unit 100 may be rotated and operated while being accommodated in an accommodation space S provided inside the second support unit 200 (e.g., at least a portion of the first support unit 100 may be located within the accommodation space S), and move relative to the second support unit 200. For example, referring to FIG. 1 and FIG. 2, in a center CP area (an area near the central axis CA) of the second support unit 200, the accommodation space S may be located to accommodate the first support unit of 100, and the first support unit 100 may be operated in a direction parallel to the central axis CA within the accommodation space S (e.g., may be moved parallel to the central axis CA) while the first support unit 100 is coupled to the first support frame 130 and the first friction reducing member 140.

In some example embodiments, the first support unit 100 and the second support unit 200 may move relative to each other in the direction parallel to the central axis CA. Accordingly, a height difference between the upper surfaces of the first substrate mount 110 and the upper surface of the second substrate mount 210 may be variable. Thus, the substrate WF to be cleaned may be supported on the first substrate mount 110 or the second substrate mount 210 depending on which of the substrate mounts 110, 210 has a relatively higher upper surface at the time. For example, the substrate WF may be mounted on the first surface 110a of the first substrate mount 110 and the second surface 210a of the second substrate mount 210 when the first surface 110a and the second surface 210a are aligned on a single plane (e.g., the same plane), and then, as the first support unit 100 remains in place while the second support unit 200 descends, the first cleaning area CL1 of the substrate WF may be supported by the first support unit 100 and the second cleaning area CL2 of the substrate WF may be exposed below the substrate WF (for example, the negative Z-axis direction in FIG. 1 and FIG. 2). Conversely, as the first support unit 100 is lowered while the second support unit 200 remains in place, the second cleaning area CL2 of the substrate WF may be supported by the second support unit 200 and the first cleaning area CL1 of the substrate WF may be exposed below the substrate WF (for example, the negative Z-axis direction in FIGS. 1 and 2). Alternatively, in some embodiments the substrate cleaning apparatus may cause one of the support units 100, 200 to lift the substrate above the other support unit in place of lowering a substrate.

In some example embodiments, when the first support unit 100 supports and rotates the substrate WF, a second nozzle unit 400 cleans the second cleaning area CL2, which is exposed on the substrate WF, and when the second support unit 200 supports and rotates the substrate WF, a first nozzle unit 300 cleans the first cleaning area CL1, which is exposed on the substrate WF.

Referring to FIG. 1 and FIG. 2, the substrate cleaning apparatus 10 may include the first nozzle unit 300 which may be slidably connected to the first support unit 100. The first nozzle unit 300 may be configured to move relative to the first support unit 100 and spray the cleaning fluid on the first cleaning area CL1 of the substrate WF when the first support unit 100 is spaced apart from the first cleaning area CL1, and the second nozzle unit 400 may be configured to spray cleaning fluid on the second cleaning area CL2 of the substrate WF when the second cleaning area CL2 is spaced apart from the second support unit 200.

In some example embodiments, the first nozzle unit 300 is connected to the first support unit 100 in a manner in which the first nozzle unit 300 may be slidably moved relative to the first support unit 100, and may be accommodated in the accommodation space S of the second support unit 200 together with the first support unit 100. Referring to FIG. 1 to FIG. 3, the first nozzle unit 300 may include a first nozzle support 320 extending along the central axis CA of the first support unit 100 and inserted into the first supporting body 120, and a first nozzle head 310 extending in a direction perpendicular to the central axis CA (for example, in the direction parallel to the X-Y plane, or a radial direction) from the end portion of the first nozzle support 320, and having a plurality of nozzle holes 312 configured to spray the cleaning fluid. The first nozzle head 310 in combination with the plurality of nozzle holes 312 collectively form a first nozzle for directing a spray of the cleaning fluid.

In some example embodiments, the first nozzle head 310 extends in a direction perpendicular to the extension direction of the first nozzle support 320 and the first nozzle head 310 may be formed as a bar-shaped structure with the plurality of nozzle holes 312 formed on the upper surface of the first nozzle head 310. With the substrate WF settled (e.g., mounted) in the substrate cleaning apparatus 10, the first nozzle head 310 of the first nozzle unit 300 may face the first cleaning area CL1 of the substrate WF.

In some example embodiments, the first nozzle head 310 of the first nozzle unit 300 may be accommodated inside the first support unit 100 to avoid interference with the substrate WF when the first support unit 100 supports the first cleaning area CL1 of the substrate WF. For example, referring to FIG. 2, the first nozzle head 310 may be accommodated in a receiving recess 112 formed in the first substrate mount 110 of the first support unit 100. For example, the receiving recess 112 may be formed on the upper surface of the first substrate mount 110 of the first support unit 100 to have a shape corresponding to the shape of the first nozzle head 310, and the first nozzle head 310 may be inserted into the receiving recess 112 such that the first nozzle may not come into contact with the substrate WF when the first support unit 100 is supporting the substrate WF. For example, when the first nozzle head 310 is accommodated in the receiving recess 112, the upper surface of the first nozzle head 310 may not protrude further toward the upper side than the first surface 110a of the first substrate mount 110.

In some example embodiments, the first nozzle unit 300 may be configured to move relative to the first support unit 100. In a state in which the first support unit 100 has descended and the second support unit 200 supports the second cleaning area CL2 of the substrate WF, the first nozzle unit 300 is moved to the upper side compared to the first support unit 100 and is positioned closer to the first cleaning area CL1 relative to the first support unit 100 of the substrate WF to spray the cleaning fluid.

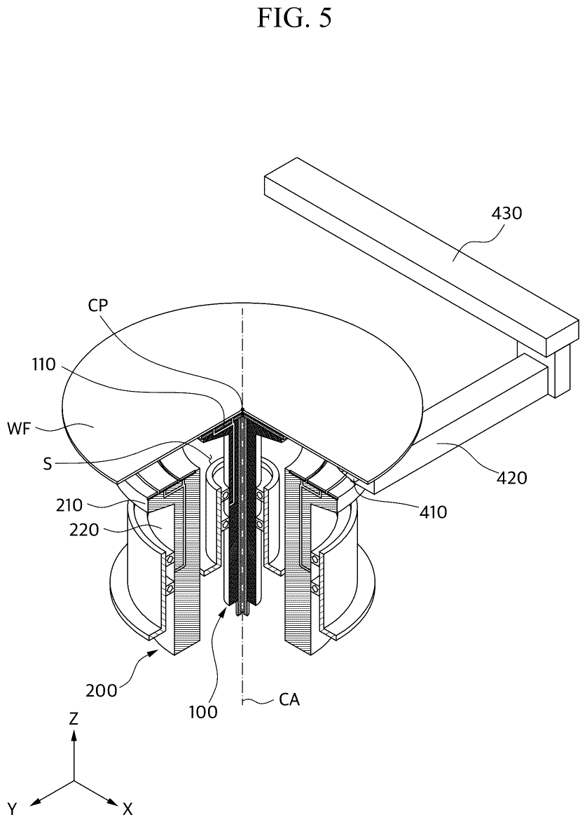

In some example embodiments, the first nozzle unit 300 may rotate together with the first support unit 100 when the first support unit 100 rotates. For example, the first nozzle unit 300 may be configured to be raised and lowered in the direction parallel to the central axis CA with respect to the first support unit 100, but configured to be dependent on the first support unit 100 in terms of the rotating operation. A detailed description of the operation of the first nozzle unit 300 will be described later with reference to FIGS. 5 to 8.

Further, referring to FIG. 1 and FIG. 2, in some example embodiments, the substrate cleaning apparatus 10 may further include the second nozzle unit 400 configured to spray the cleaning fluid on the second cleaning area CL2 of the substrate WF.

In some example embodiments, the second nozzle unit 400 may be spaced apart from the first support unit 100 and the second support unit 200. For example, the second nozzle unit 400 may include a second nozzle guide 430 arranged on one side of the second support unit 200, a second nozzle support 420 that may slide along the length of the second nozzle guide 430, and a second nozzle 410, which is placed at the end portion of the second nozzle support 420 and sprays the cleaning fluid.

In some example embodiments, the second nozzle guide 430 may have a guide rail structure in which the second nozzle guide 430 extends along the direction parallel to the surface of the substrate WF (for example, the X-axis direction) and that guides the movement direction of the second nozzle 410. Being supported by the second nozzle support 420, the second nozzle 410 may spray the cleaning fluid onto the bottom of the substrate WF by sliding along the extension direction (for example, in the X-axis direction) of the second nozzle guide 430 together with the second nozzle support 420.

Referring to FIG. 1 and FIG. 2, in some example embodiments, the second nozzle 410 may be formed as a single injector type with a width that gradually narrows toward the end portion. With this structure, the second nozzle 410 may be configured to be lightweight, and the second nozzle 410 may be accurately and quickly moved, even with a small driving force. However, the specific structure of the second nozzle 410 is not limited to that illustrated in the drawings. For example, the second nozzle 410, like the first nozzle head 310, may be formed as a bar-shaped structure with a plurality of nozzle holes arranged on the upper surface of the second nozzle 410.

In some example embodiments, the cleaning fluid sprayed by the first nozzle unit 300 and the second nozzle unit 400 may include various types of cleaning liquids and gases. For example, the cleaning liquid sprayed by the substrate cleaning apparatus 10 may include at least one selected from the group consisting of water, distilled water, deionized water, SC-1 (ammonia/peroxide mixture), SC-2 (hydrochloric acid/hydrogen peroxide mixture), hydrofluoric acid (such as ash hydrofluoric acid), hydrogen peroxide, sulfuric acid, or nitric acid. However, in addition to those described above, any liquid that is used for cleaning the substrate WF of the semiconductor may be applied without limitation. Further, the substrate cleaning apparatus 10 may clean the substrate WF by spraying a high-temperature, high-pressure mist-type cleaning fluid, which is a mixture of a high-temperature cleaning liquid (for example, cleaning liquids above about 120° C.) and a high-pressure gas (for example, gases with a pressure of 5 bar or more), onto the substrate WF. For this, the substrate cleaning apparatus 10 may further include a tank storing the cleaning fluid and a pump for increasing the injection pressure of the cleaning fluid. As such, according to some example embodiments, the substrate WF treatment device may spray the high temperature and high pressure cleaning fluid onto the surface of the substrate WF, and thus effectively remove foreign substances or unnecessary material layers on the surface of the substrate WF by utilizing the temperature and kinetic energy of the cleaning fluid.

Referring to FIG. 4, in an example embodiment, the substrate cleaning apparatus 10 may further include a controller 500 that comprehensively controls operations of the first support unit 100, the second support unit 200, the first nozzle unit 300 and the second nozzle unit 400. For example, the controller 500 may control the rotation of the substrate WF through controlling the rotating operation of the first support unit 100 and the second support unit 200. For example, each of the support units 100, 200 may have an associated motor or rotary actuator under control of the controller 500 to cause the corresponding support units 100, 200 to rotate. The controller 500 may also control the lifting and lowering of the support units 100, 200 to selectively support the substrate WF. For example, each of the support units 100, 200 may have an associated motor or linear actuator under control of the controller 500 to cause the corresponding support units 100, 200 to raise or lower (e.g., extend or retract relative to one another. Further, the controller 500 may control the cleaning of the first cleaning area CL1 and the second cleaning area CL2 of the substrate WF to be cleaned sequentially by controlling the movement and the cleaning fluid spraying operation of the first nozzle unit 300 and the second nozzle unit 400 based on the state of the first support unit 100 and the second support unit 200. For example, the controller 500 may cause the cleaning of the first cleaning area CL1 when the substrate WF is supported and rotated by the second support unit 200 and cause the cleaning of the second cleaning area CL2 when the substrate WF is supported and rotated by the first support unit 100.

Although not illustrated, the controller 500 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller 500 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller 500 can include antennas, network interfaces that provide wireless and/or wire line digital and/or analog interface to one or more networks over one or more network connections (not shown), a power source that provides an appropriate alternating current (AC) or direct current (DC) to power one or more components of the controller 500, and a bus that allows communication among the various disclosed components of the controller 500.

Hereinafter, a substrate WF cleaning process by the substrate cleaning apparatus 10 according to example embodiments will be described in more detail with reference to FIGS. 5 to 8.

First, example embodiments are described referring to FIG. 5 and FIG. 6 in which the substrate WF is cleaned by the second nozzle unit 400 while the first support unit 100 supports the substrate WF.

FIG. 5 is a reference diagram for explaining a portion of the substrate WF being cleaned while the first support unit 100 supports the substrate WF according to an example embodiment.

FIG. 6 is an exemplary cross-sectional view of the substrate cleaning apparatus 10 with the first support unit 100 supporting the substrate WF according to an example embodiment.

FIG. 5 and FIG. 6 illustrate that when the first support unit 100 of the substrate cleaning apparatus 10 rotates while supporting the substrate WF, the second nozzle unit 400 cleans the second cleaning area (for example, the second cleaning area CL2 in FIG. 2) of the substrate WF. For example, in the state where the first substrate mount 110 of the first support unit 100 and the second substrate mount 210 of the second support unit 200 are aligned on the same plane, such as the substrate WF to be cleaned is settled, the second support unit 200 may descend relative to the first support unit 100 such that the second support unit 200 no longer supports the substrate WF. The first support unit 100 may then be rotated and the substrate WF may rotate together with the first support unit 100 while being supported only by the first support unit 100 as illustrated in FIG. 5 and FIG. 6.

In some example embodiments, the first support unit 100 and the second support unit 200 may be driven independently of each other under the control of a controller (for example, the controller 500 in FIG. 4). For example, the controller 500 may control the rotating operation of the first support unit 100 and the lifting operation of the second support unit 200 to be performed simultaneously or sequentially.

In an example embodiment, the substrate WF may be placed in the substrate cleaning apparatus 10 with the center CP to be positioned on the central axis CA of the first support unit 100 of the substrate cleaning apparatus 10. However, the settling position of the substrate WF is not limited to that described above. If the substrate WF is stably supported on the first support unit 100, the center CP of the substrate WF may be positioned slightly misaligned with the central axis CA of the first support unit 100.

In an example embodiment, if the substrate WF is completely settled on the upper surface of the first support unit 100, the controller 500 may lower the second support unit 200 and rotate the first support unit 100 in order for the substrate WF to rotate while being supported on the first support unit 100.

In an example embodiment, the substrate WF may be vacuum-adsorbed onto the first substrate mount 110 of the first support unit 100, and as the first support unit 100 rotates around the central axis CA, the substrate WF may rotate together with the first support unit 100. As described above with reference to FIG. 1 to FIG. 4, on the first surface 110a wherein the substrate WF is settled in the first substrate mount 110, the plurality of vacuum holes 111 connected to a vacuum line are provided, and after the substrate WF is settled, negative pressure is formed in the vacuum line VL1 of the first support unit 100 to adsorb and support the substrate WF. As such, since the substrate WF is vacuum-adsorbed and the relative position with respect to the first support unit 100 is fixed, the first support unit 100 may stably rotate the substrate WF without damaging the substrate WF. While the first support unit 100 supports the substrate WF, the first nozzle head 310 of the first nozzle unit 300 may be accommodated within the receiving recess 112 formed on the upper surface of the first substrate mount 110 and may not come into contact with the substrate WF.

In an example embodiment, while the first support unit 100 supports a first cleaning area (for example, the first cleaning area CL1 in FIG. 2) of the substrate WF, the second support unit 200 is lowered so that the second substrate mount 210 and the substrate WF are separated, and accordingly, a second cleaning area (for example, the second cleaning area CL2 in FIG. 2) of the substrate WF may be exposed without any part being covered by the second support unit 200. Referring to FIG. 6, the second nozzle 410 of the second nozzle unit 400 may spray the cleaning fluid into the second cleaning area CL2 of the substrate WF by entering a gap formed between the second substrate mount 210 and the substrate WF and moving along the direction parallel to the bottom of the substrate WF (or the direction perpendicular to the central axis CA). While the cleaning fluid is sprayed by the second nozzle unit 400, the substrate WF may also be rotated continuously by the rotation of the first support unit 100, and accordingly, the cleaning fluid is evenly sprayed onto the second cleaning area CL2 of the substrate WF to clean the entire second cleaning area CL2.

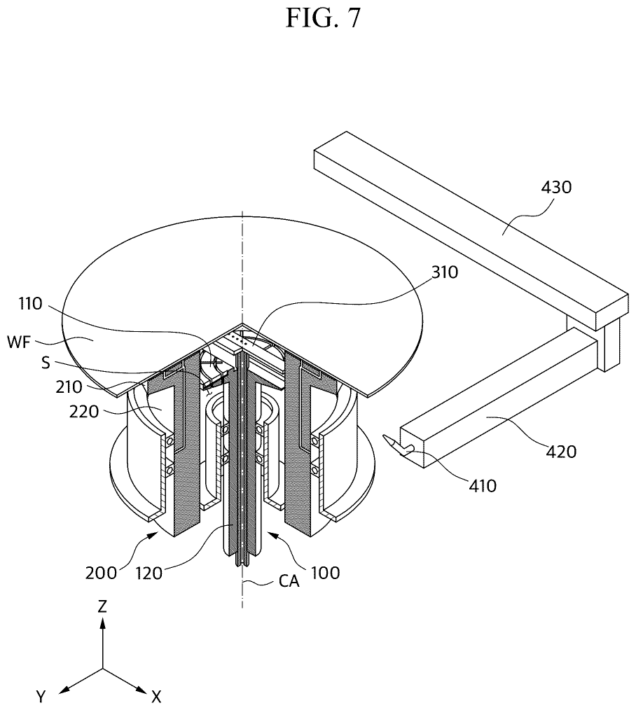

Hereinafter, described with reference to FIG. 7 and FIG. 8 are example embodiments in which the substrate WF is cleaned by the first nozzle unit 300 while the second support unit 200 supports the substrate WF.

FIG. 7 is a reference diagram for explaining an example in which a portion of the substrate WF is cleaned while the second support unit 200 supports the substrate WF according to an example embodiment.

FIG. 8 is an exemplary cross-sectional view of the substrate cleaning apparatus 10 illustrating a state in which the second support unit 200 supports the substrate WF according to an example embodiment.

FIG. 7 and FIG. 8 illustrate the first nozzle unit 300 cleaning the first cleaning area (for example, the first cleaning area CL1 in FIG. 2) of the substrate WF while the second support unit 200 of the substrate cleaning apparatus 10 rotates while supporting the substrate WF. For example, in the state in which the first substrate mount 110 of the first support unit 100 and the second substrate mount 210 of the second support unit 200 are aligned on the same plane, the substrate WF to be cleaned is settled. Then, the first support unit 100 descends and the second support unit 200 rotates, and the substrate WF may rotate together with the second support unit 200 while being supported only by the second support unit 200 as illustrated in FIG. 7 and FIG. 8. Alternatively, as illustrated in FIG. 5 and FIG. 6, in the state that the substrate WF is supported by the first support unit 100, after the first support unit 100 stops rotating, the first support unit 100 descends and the second support unit 200 ascends until the substrate WF is supported by only the second support unit 200. Accordingly, the substrate WF may then rotate together with the second support unit 200 while being supported only by the second support unit 200 as illustrated in FIG. 7 and FIG. 8.

In example embodiment, the substrate WF may rotate together with the second support unit 200 while being vacuum-adsorbed on the second substrate mount 210 of the second support unit 200 and as the second support unit 200 rotates having the central axis CA as the center. As described with reference to FIG. 1 to FIG. 4, with respect to the second substrate mount 210, the plurality of vacuum holes 211 connected to a vacuum line are provided on the second surface 210a on which the substrate WF is mounted, and after the substrate WF is settled, negative pressure is formed in the vacuum line VL2 of the second support unit 200 to adsorb and secure the substrate WF. As such, as the substrate WF is vacuum-adsorbed and the relative position is fixed with respect to the second support unit 200, the second support unit 200 may stably rotate the substrate WF without damaging the substrate WF. Meanwhile, while the second support unit 200 supports the substrate WF, the second nozzle 410 of the second nozzle unit 400 may be fixed at a position spaced apart from the second support unit 200 in order to avoid interference between the second substrate mount 210 and the substrate WF.

In an example embodiment, while the second support unit 200 supports the second cleaning area CL2 of the substrate WF, the first support unit 100 descends inside the accommodation space S of the second support unit 200, and accordingly, the first substrate mount 110 is spaced apart from the substrate WF so that the first cleaning area CL1 of the substrate WF may be exposed without any part being covered by the first support unit 100. The first nozzle unit 300 accommodated in the first support unit 100 may perform cleaning by spraying the cleaning fluid onto the exposed first cleaning area CL1 of the substrate WF.

In an example embodiment, the first nozzle unit 300 may be driven upward from the first support unit 100 toward the substrate WF (for example, the positive direction of the Z axis) so as to spray the cleaning fluid at a position closer to the substrate WF. Accordingly, the first nozzle unit 300 may be pulled out of the receiving recess 112 of the first support unit 100 and protrude toward the upper side of the first substrate mount 110.

In an example embodiment, inside the first nozzle unit 300, a flow path may be formed along the direction parallel to the central axis CA, and the cleaning fluid may flow along the flow path and be sprayed onto the substrate WF through the nozzle holes 312 of the first nozzle head 310.

In an example embodiment, while the cleaning fluid is sprayed by the first nozzle unit 300, the substrate WF may also be rotated continuously by the rotation of the second support unit 200, and accordingly, the cleaning fluid may be evenly sprayed onto the first cleaning area CL1 of the substrate WF. In this example, the first nozzle head 310 of the first nozzle unit 300 has a bar-shaped structure extending in the direction parallel to the bottom of the substrate WF (for example, in the X-axis direction), and the plurality of nozzle holes 312 are disposed along the longitudinal direction (for example, the X-axis direction) of the first nozzle head 310 on the upper surface of the first nozzle head 310, and thus, even if the cleaning fluid is sprayed in a place without separate slide movement, with the rotation of the substrate WF by the second support unit 200, the cleaning fluid may evenly sprayed onto the first cleaning area CL1 of the substrate WF and the first cleaning area CL1 may be completely cleaned.

In the substrate cleaning apparatus 10 according to an example embodiment, the cleaning process of the second cleaning area CL2 illustrated in FIG. 5 and FIG. 6 and the cleaning process of the first cleaning area CL1 illustrated in FIG. 7 and FIG. 8 may be alternately repeated. The controller (for example, the controller 500 in FIG. 4) may perform the cleaning process by controlling the operations of the first support unit 100, the second support unit 200, the first nozzle unit 300 and the second nozzle unit 400 simultaneously or sequentially.

An overview of some embodiments of the substrate WF cleaning method using the substrate cleaning apparatus 10 described above is summarized as follows.

In an example embodiment, the method for cleaning the substrate WF using the substrate cleaning apparatus 10 may include an operation in which the first support unit 100 rotates around the central axis CA while supporting the substrate in the first cleaning area CL1, an operation in which the second support unit 200, in which the accommodation space S accommodating the first support unit 100 is formed, is moved in the direction parallel to the central axis CA so as to be spaced apart from the substrate WF, and an operation in which the second nozzle unit 400 sprays the cleaning fluid onto substrate in the second cleaning area CL2, which is outside the first cleaning area CL1 of the substrate WF. Here, for specific operations of the first support unit 100, the second support unit 200, the first nozzle unit 300 and the second nozzle unit 400, descriptions with reference to FIG. 5 and FIG. 6 may be referred to.

Further, in an example embodiment, the method for cleaning the substrate WF using the substrate cleaning apparatus 10 may further include an operation in which while the second nozzle unit 400 sprays the cleaning fluid onto the substrate WF, the second nozzle unit 400 sprays the cleaning fluid while moving in the direction perpendicular to the central axis CA in a gap formed between the second support unit 200 and the substrate WF.

Further, in an example embodiment, the method for cleaning the substrate WF using the substrate cleaning apparatus 10 may include an operation in which the first support unit 100 stops rotating and descends in the direction parallel to the central axis CA inside the accommodation space S of the second support unit 200 and is then separated from the substrate WF by the first gap (for example, a first gap d1 in FIG. 8), an operation that the second support unit 200 rotates around the central axis CA while supporting the substrate WF in the second cleaning area CL2, and an operation that the first nozzle unit 300 sprays the cleaning fluid onto the first cleaning area CL1 of the substrate WF. Here, for specific operations of the first support unit 100, the second support unit 200, the first nozzle unit 300 and the second nozzle unit 400, descriptions with reference to FIG. 7 and FIG. 8 may be referred to.

Further, in an example embodiment, the method for cleaning the substrate WF using the substrate cleaning apparatus 10 may further include an operation that the first nozzle unit 300 rises in the direction that is from the first support unit 100 toward the substrate WF in order for the first nozzle unit 300 to be spaced apart from the substrate WF by a second gap (for example a second gap d2 of FIG. 8) that is smaller than the first gap d1.

Further, in an example embodiment, according to the substrate WF cleaning method using the substrate cleaning apparatus 10, the operations may be alternately repeated. For example, the operation in which the first support unit 100, in which the first nozzle unit 300 is accommodated, rotates around the central axis CA while supporting the first cleaning area CL1 on one side of the substrate WF, and an operation that the second support unit 200 rotates around the central axis CA while supporting the second cleaning area CL2 of the substrate WF may be alternately repeated. Accordingly, the first cleaning area CL1 and the second cleaning area CL2 may be cleaned alternately.

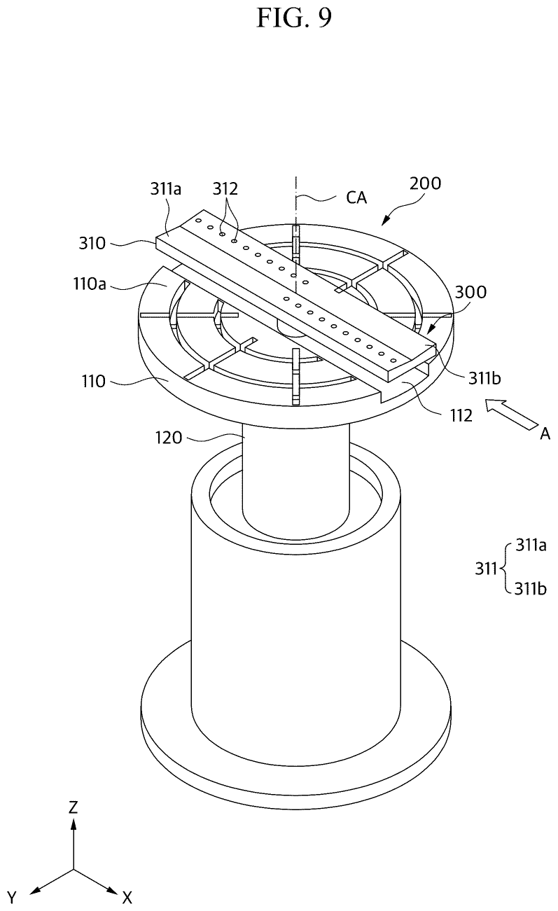

Hereinafter, the structure of the first nozzle unit 300 included in the substrate cleaning apparatus 10 according to various example embodiments will be described in more detail with reference to FIGS. 9 to 14.

Technology features of the substrate cleaning apparatus 10 to be described with reference to FIG. 9 to FIG. 14 include all the technology features of the substrate cleaning apparatus 10 described above with reference to FIG. 1 to FIG. 8, and thus repeated descriptions may be omitted.

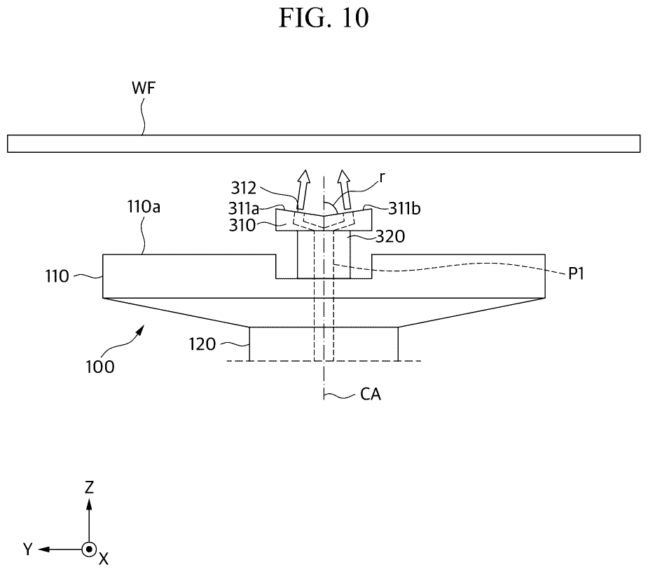

FIG. 9 is an exemplary perspective view of the first support unit 100 and the first nozzle unit 300 of the substrate cleaning apparatus 10 according to an example embodiment, and FIG. 10 is an exemplary side view that is viewed from the “A” direction of FIG. 9.

Referring to FIG. 9 and FIG. 10 together, in an example embodiment, the first nozzle unit 300 may have the first nozzle head 310 having a spraying surface 311 having the plurality of nozzle holes 312 formed therein, and the first nozzle support 320 extending in the direction parallel to the central axis CA of the first support unit 100 from the first nozzle head 310. The cleaning fluid may be introduced toward the first nozzle head 310 along a first flow path P1 formed inside the first nozzle support 320, and then the cleaning fluid may be sprayed onto the substrate WF through the plurality of nozzle holes 312.

In an example embodiment, the first substrate mount 110 of the first support unit 100 may include the receiving recess 112 in which the first nozzle head 310 is received. The receiving recess 112 may be formed as a recessed structure corresponding to the shape of the first nozzle head 310. The height of the first nozzle head 310 may be lower than or equal to the depth of the receiving recess 112. Therefore, in the state that the first nozzle head 310 is mounted on the lower portion surface of the receiving recess 112, the uppermost part of the first nozzle head 310 may not protrude to the upper side of the first surface 110a of the first substrate mount 110. Accordingly, the first nozzle head 310 and the substrate WF may be prevented from colliding in the process of the substrate WF being mounted on the first substrate mount 110.

In an example embodiment, in order to effectively clean the first area of the substrate WF, the first nozzle unit 300 may be driven upward relative to the first support unit 100. Accordingly, as illustrated in FIG. 9 and FIG. 10, the first nozzle head 310 may be detached from the receiving recess 112 of the first substrate mount 110 and protrude to the upper side of the first substrate mount 110.

In an example embodiment, the plurality of nozzle holes 312 in the spraying surface 311 of the first nozzle head 310 may be arranged along the longitudinal direction (for example, the X-axis direction of FIG. 9 and FIG. 10) of the first nozzle head 310.

In an example embodiment, the spraying surface 311 of the first nozzle head 310 may be formed to be inclined with respect to the first surface 110a of the first support unit 100. For example, referring to FIG. 9 and FIG. 10, a first spraying surface 311a and a second spraying surface 311b of the first nozzle head 310 may be formed at an angle to each other so that the angle therebetween forms an obtuse angle, and the same time, each of the first spraying surface 311a and the second spraying surface 311b may be formed at an angle to the first surface 110a of the first support unit 100. In other words, the first spraying surface 311a or the second spraying surface 311b of the first nozzle head 310 may have a structure inclined so that the angle (r) between the first spraying surface 311a or the second spraying surface 311b and the central axis CA is less than 90 degrees.

In an example embodiment, the nozzle holes 312 of the first nozzle head 310 may be configured to spray the cleaning fluid in the direction perpendicular to each of the first spraying surface 311a and the second spraying surface 311b. Accordingly, from the first nozzle head 310, the cleaning fluid may be sprayed in an oblique direction with respect to the substrate WF. According to the injection structure that injects the cleaning fluid obliquely to the substrate WF, the relative velocity of the cleaning fluid with respect to the rotating substrate WF may be increased, when compared to the case where the cleaning fluid is sprayed in a direction perpendicular to the rotating substrate WF. Therefore, the substrate WF may be cleaned more effectively because the cleaning fluid may collide more strongly with the surface of the substrate WF.

In the first nozzle head 310 structure, in which the cleaning fluid is sprayed obliquely onto the surface of the substrate WF, the plurality of nozzle holes 312 may be arranged in order for the flow of the cleaning fluid sprayed from one spraying surface (for example, the first spraying surface 311a) not to interfere with the flow of the cleaning fluid sprayed from the other spraying surface (for example, the second spraying surface 311b). For example, referring to FIG. 9, the plurality of nozzle holes 312 may be concentratedly arranged on one side based on the central axis CA on the first spraying surface 311a, and the plurality of nozzle holes 312 may be concentratedly arranged on the other side based on the central axis CA on the second spraying surface 311b. As such, the plurality of nozzle holes 312 may be arranged on the first nozzle head 310 in order to be rotationally symmetric about the central axis CA.

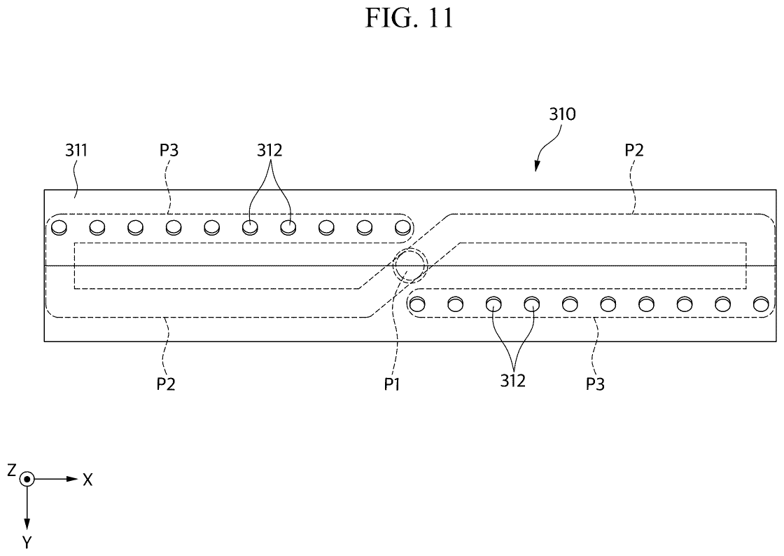

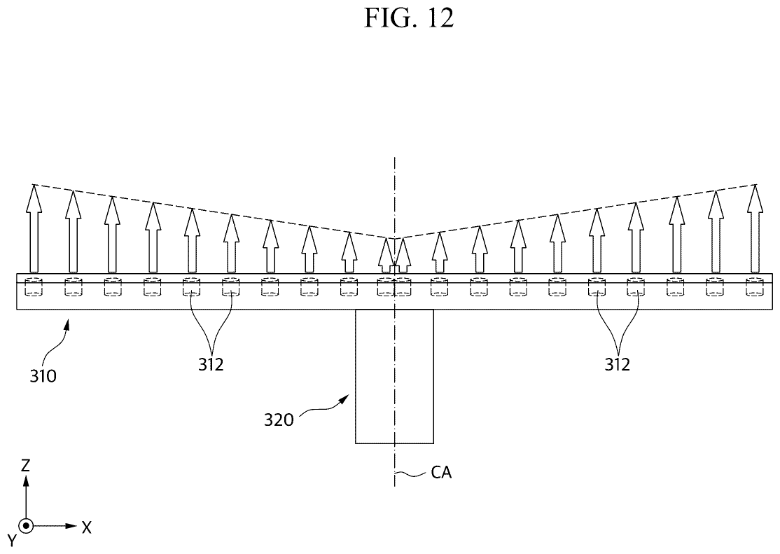

FIG. 11 is a top view of the first nozzle unit 300 included in the substrate cleaning apparatus 10 according to an example embodiment, and FIG. 12 is a front view of the first nozzle unit 300 according to the example embodiment illustrated in FIG. 11.

In an example embodiment, the first nozzle unit 300 may include the first flow path P1 formed in the direction parallel to the central axis CA inside the first nozzle support 320, a second flow path P2 connected to the first flow path P1, and a third flow path P3 connected to the second flow path P2.

In an example embodiment, the second flow path P2 and the third flow path P3 may extend at least partially along the length direction (for example, in the X-axis direction) of the first nozzle head 310. For example, referring to FIG. 11, the second flow path P2 extends along the longitudinal direction (for example, the X-axis direction) of the first nozzle head 310. An end portion of a first side of the second flow path P2 may be connected to the first flow path P1, and an end portion of a second side of the second flow path P2 may be connected to the third flow path P3. Further, an end portion of the third flow path P3 may be connected to the second flow path P2, and be extended parallel to the second flow path P2 in the direction toward the first flow path P1.

In an example embodiment, the plurality of nozzle holes 312 may be arranged along the third flow path P3 on the upper surface of the first nozzle head 310. Accordingly, the cleaning fluid may go through the first flow path P1, the second flow path P2 and the third flow path P3 sequentially, and may be sprayed to the upper side of the first nozzle head 310 through the plurality of nozzle holes 312 connected to the third flow path P3. Here, the cleaning fluid is sprayed at the strongest pressure from the nozzle hole 312 located at the beginning of the third flow path P3, and pressure of the cleaning fluid gradually decreases as the nozzle hole is located farther away from the beginning of the third flow path P3, and thus the cleaning fluid may be sprayed at the weakest pressure from the nozzle hole 312 located at the end portion of the third flow path P3. For example, as illustrated in FIG. 12, the cleaning fluid may be sprayed at the strongest pressure from both ends in the longitudinal direction (for example, in the X-axis direction) of the first nozzle head 310, and as the nozzle holes 312 get closer to the central axis CA, the injection pressure gradually decreases, and thus the cleaning fluid may be sprayed at the weakest pressure near the central axis CA.

According to the flow path structure, the bevel edge portion of the first cleaning area of the substrate WF (for example, the first cleaning area CL1 in FIG. 2) may be cleaned with a stronger cleaning pressure. Specifically, during the deposition process of the upper surface of the substrate WF, when process gas flows into the bottom along the bevel edge of the substrate WF and an unnecessary material layer is gradually deposited from the bevel edge of the bottom of the substrate WF, the bevel edge of the bottom of the substrate WF may form a material layer thicker than the center CP of the bottom of the substrate WF. As illustrated in FIG. 11 and FIG. 12, the substrate cleaning apparatus 10 according to an example embodiment may effectively clean a material layer that becomes thicker as it moves away from the center CP in the first cleaning area CL1 of the bottom of the substrate WF by spraying the cleaning fluid at the strongest pressure near both of the end portions in the longitudinal direction of the first nozzle unit 300.

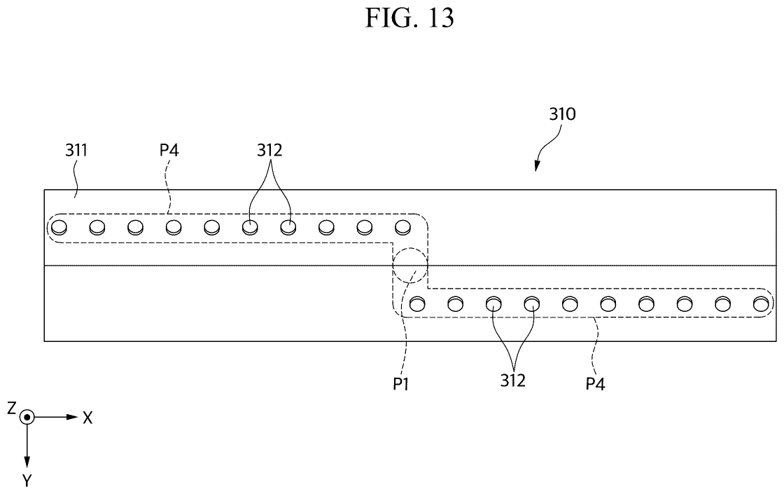

FIG. 13 is a top view of the first nozzle unit 300 included in the substrate cleaning apparatus 10 according to an example embodiment.

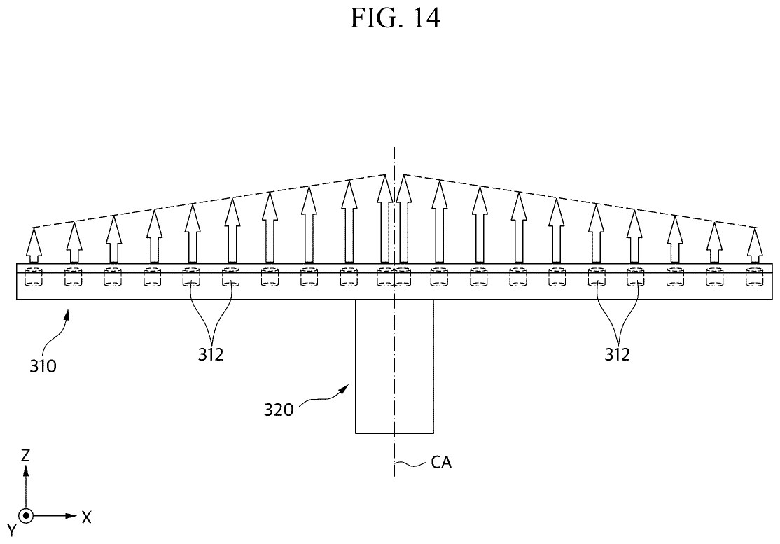

FIG. 14 is a front view of the first nozzle unit 300 according to the example embodiment illustrated in FIG. 13.

In another example embodiment, the first nozzle unit 300 may include the first flow path P1 formed in the direction parallel to the central axis CA within the first nozzle support 320, and a fourth flow path P4 that is connected to the first flow path P1 and extends in the longitudinal direction (for example, the X-axis direction) of the first nozzle head 310.

In an example embodiment, the plurality of nozzle holes 312 may be arranged along the fourth flow path P4 on the upper surface of the first nozzle head 310. Accordingly, while the cleaning fluid goes through the first flow path P1 and the fourth flow path P4 sequentially, the cleaning fluid may be sprayed to the upper side of the first nozzle head 310 through the plurality of nozzle holes 312 connected to the fourth flow path P4. Here, the cleaning fluid is sprayed at the strongest pressure from the nozzle hole 312 located at the beginning of the fourth flow path P4, and pressure of the cleaning fluid gradually decreases as the nozzle hole is located farther away from the beginning of the fourth flow path P4, and thus the cleaning fluid may be sprayed at the weakest pressure from the nozzle hole 312 located at the end portion of the fourth flow path P4. For example, as illustrated in FIG. 14, the cleaning fluid may be injected at the strongest pressure in the area near the central axis CA of the first nozzle head 310, and as the holes get closer to the both end portions in the longitudinal direction (for example, the X-axis direction) of the first nozzle head 310, the spray pressure of the cleaning fluid may be gradually reduced.

According to the flow path structure, the center part of the first cleaning area of the substrate WF (for example, the first cleaning area CL1 in FIG. 2) may be cleaned with the stronger cleaning pressure. For example, when more foreign substances or unnecessary material layers are formed in the center part of the substrate WF, as illustrated in FIG. 13 and FIG. 14, by spraying the cleaning fluid with the strongest pressure in the area near the central axis CA of the first nozzle unit 300, the center part of the bottom of the substrate WF may be effectively cleaned.

As described above, the substrate cleaning apparatus 10 according to the example embodiments may effectively clean the bottom (or the surface to be cleaned) of the substrate WF while supporting the bottom of the substrate WF.

Specifically, the substrate cleaning apparatus 10 according to the example embodiments may effectively clean the substrate without contacting any part other than the bottom of the substrate WF by dividing the bottom of the substrate WF into a plurality of areas and cleaning the plurality of areas sequentially.

Further, through a plurality of support units that are each configured to perform the lifting operation and the rotating operation and a plurality of nozzle units configured to clean different areas to be cleaned, the substrate cleaning apparatus 10 according to the example embodiments may stably clean unnecessary material layers or contaminants on the bottom of the substrate WF without physically or chemically damaging the upper surface of the substrate WF on which an effective material layer is formed.

In the above, various embodiments of the present disclosure are described in detail. However, it will be apparent to those with average knowledge in the technical field that scope of rights of this disclosure is not limited thereto, and various modifications and variations are possible without departing from the technical spirit of the present. Further, the above-described example embodiments may be implemented with some elements deleted, and each example embodiment may be implemented in combination with each other.

What is claimed is:

1. A substrate cleaning apparatus comprising:
a first support unit having a first support surface extending to a first radius and configured to support a substrate at a first cleaning area of the substrate when the substrate is loaded in the substrate cleaning apparatus, the first support unit configured to rotate around a central axis;
a second support unit having an accommodation space accommodating the first support unit, the second support unit having a second support surface extending from a second radius larger than the first radius to a third radius larger than the second radius and configured to support the substrate at a second cleaning area when the substrate is loaded in the substrate cleaning apparatus, the second support unit being configured to rotate around the central axis;
a first nozzle unit configured to spray a cleaning fluid upward at an area within the second radius onto the first cleaning area of the substrate when the substrate is supported by the second support unit; and
a second nozzle unit configured to spray the cleaning fluid upward at an area external to the first radius onto the second cleaning area of the substrate when the substrate is supported and rotated by the first support unit.

2. The substrate cleaning apparatus of claim 1, wherein the first support unit is configured to move in a direction parallel to the central axis within the accommodation space formed in the second support unit.

3. The substrate cleaning apparatus of claim 1, wherein the first nozzle unit is configured to move along a direction parallel to the central axis with respect to the first support unit.

4. The substrate cleaning apparatus of claim 3, wherein the first nozzle unit is configured to rotate together with the first support unit.

5. The substrate cleaning apparatus of claim 3, wherein the first nozzle unit comprises:
a first nozzle support that extends in the direction parallel to the central axis inside of the first support unit, and that has a first flow path for the cleaning fluid; and
a first nozzle head that extends in a direction perpendicular to the central axis from an end portion of the first nozzle support, and that comprises a plurality of nozzle holes configured to spray the cleaning fluid.

6. The substrate cleaning apparatus of claim 5, wherein the first support unit has an upper surface having a receiving recess formed therein accommodating the first nozzle head.

7. The substrate cleaning apparatus of claim 5, wherein the first nozzle head comprises:
a first spraying surface formed at a first angle with respect to the central axis and where a first group of nozzle holes of the plurality of nozzle holes are arranged; and
a second spraying surface formed at a second angle with respect to the central axis and where a second group of nozzle holes of the plurality of nozzle holes not in the first group of nozzle holes are arranged,
wherein the first spraying surface and the second spraying surface together form an obtuse angle.

8. The substrate cleaning apparatus of claim 5, wherein the first nozzle unit further comprises:
a second flow path that extends in a longitudinal direction of the first nozzle head and has an end portion connected to the first flow path; and
a third flow path that extends in a direction parallel to an extension direction of the second flow path toward the first flow path and has an end portion connected to the second flow path, and
wherein the plurality of nozzle holes are arranged along the third flow path on an upper surface of the first nozzle head.

9. The substrate cleaning apparatus of claim 8, wherein the first nozzle head further comprises a fourth flow path that is connected to the first flow path and extends in the longitudinal direction of the first nozzle head, and
wherein the plurality of nozzle holes are arranged along the fourth flow path on the upper surface of the first nozzle head.

10. The substrate cleaning apparatus of claim 1, wherein the first support unit comprises:
a first supporting body extending along the central axis; and
a first substrate mount connected at an end portion of the first supporting body, and configured to support at least a portion of the first cleaning area of the substrate when the substrate is loaded in the substrate cleaning apparatus,
wherein, a plurality of vacuum holes on an upper surface of the first substrate mount are configured to adsorb the substrate when the substrate is loaded in the substrate cleaning apparatus.

11. The substrate cleaning apparatus of claim 10, wherein the second support unit comprises:
a second supporting body that wraps around the first supporting body and extends along the central axis; and
a second substrate mount secured at an end portion of the second supporting body, and configured to support at least a portion of the second cleaning area of the substrate when the substrate is loaded in the substrate cleaning apparatus,
wherein, a plurality of vacuum holes on an upper surface of the second substrate mount are configured to adsorb the substrate when the substrate is loaded in the substrate cleaning apparatus.

12. The substrate cleaning apparatus of claim 10, further comprising a first friction reducing member surrounding an outer surface of the first supporting body,
wherein the first friction reducing member is placed inside the accommodation space of the second support unit.

13. The substrate cleaning apparatus of claim 1, where the second nozzle unit comprises:
a second nozzle configured to spray the cleaning fluid; and
a second nozzle support supporting the second nozzle,
wherein the second nozzle is configured to move along a direction perpendicular to the central axis.

14. The substrate cleaning apparatus of claim 13, wherein the second nozzle is configured to move along the direction perpendicular to the central axis in a space between the second support unit and the substrate when the first support unit supports and rotates the substrate.

15. A method of cleaning a substrate, the method comprising:
rotating a first support unit around a central axis with the first support unit supporting a substrate at a first cleaning area of the substrate, wherein the first support unit has a recess accommodating a first nozzle unit;
moving a second support unit in a direction parallel to the central axis to space the second support unit from the substrate, wherein the second support unit includes an accommodation space to accommodate the first support unit; and
spraying a cleaning fluid onto a second cleaning area of the substrate that is outside of the first cleaning area of the substrate with a second nozzle unit.

16. The method of cleaning the substrate of claim 15, wherein, while the second nozzle unit sprays the cleaning fluid on the substrate, the second nozzle unit moves in a direction perpendicular to the central axis in a space between the second support unit and the substrate.

17. The method of cleaning the substrate of claim 15, further comprising:
stopping rotation of the first support unit, and moving the first support unit in the direction parallel to the central axis to be spaced from the substrate by a first gap;
rotating the second support unit around the central axis while the second support unit supports the substrate in the second cleaning area; and
spraying the cleaning fluid onto the first cleaning area of the substrate with the first nozzle unit.

18. The method of cleaning the substrate of claim 17,
further comprising:
moving the first nozzle unit from the first support unit toward the substrate to be spaced from the substrate by a second gap that is smaller than the first gap.

19. The method of cleaning the substrate of claim 17, wherein,
rotating the first support unit around the central axis while the first support unit supports the substrate in the first cleaning area, and rotating the second support unit around the central axis while the second support unit supports the substrate in the second cleaning area are repeated alternately.

20. A substrate cleaning apparatus comprising:
a first support unit having a first support surface configured to support a substrate and to rotate around a central axis;
a second support unit having a second support surface configured to support the substrate at a location radially external to the first support surface and to rotate around the central axis, and move in a direction parallel to the central axis with respect to the first support unit;
a first nozzle unit coupled to the first support unit and comprising a plurality of nozzle holes arranged along a direction intersecting the central axis, wherein the plurality of nozzle holes are configured to spray a cleaning fluid at a location radially internal to the second support surface; and
a second nozzle unit disposed to be spaced from the first support unit and the second support unit, the second nozzle unit being configured to spray the cleaning fluid onto a bottom of the substrate while moving in a direction perpendicular to the central axis.
